(19) United States
(12) Patent Application Publication
(10) Pub. No.: US 2025/0133830 A1
(43) Pub. Date: Apr. 24, 2025

(54) ELECTRO-OPTIC DEVICE AND ELECTRONIC DEVICE

(71) Applicant: SEIKO EPSON CORPORATION, Tokyo (JP)

(72) Inventors: Tomoya TAKEUCHI, CHITOSE-SHI (JP); Daisuke MIYAWAKI, CHITOSE-SHI (JP)

(73) Assignee: SEIKO EPSON CORPORATION, Tokyo (JP)

(21) Appl. No.: 18/918,109

(22) Filed: Oct. 17, 2024

(30) Foreign Application Priority Data
Oct. 18, 2023 (JP) 2023-179356

(51) Int. Cl. H01L 27/12; G02F 1/1362; G02F 1/1368

(52) U.S. Cl. CPC H10D 86/60; G02F 1/136227; G02F 1/1368; H10D 86/441; H10D 86/451; H10D 86/481

(57) ABSTRACT

An electro-optic device includes a transistor, a pixel electrode provided corresponding to the transistor, a conducting film serving as a first film provided between the transistor and the pixel electrode, a reflection film provided between the conducting film and the pixel electrode and having a light reflectance higher than that of the conducting film, a relaying layer electrically connected to the pixel electrode through a contact hole extending to the conducting film through the reflection film, and a contact plug serving as a connecting member provided in the contact hole.

The present application is based on, and claims priority from JP Application Serial Number 2023-179356, filed Oct. 18, 2023, the disclosure of which is hereby incorporated by reference herein in its entirety.

### BACKGROUND

### 1. Technical Field

The present disclosure relates to an electro-optic device and an electronic device including the electro-optic device.

### 2. Related Art

Among known electro-optic devices is a device disclosed in JP-A-2019-78825, for example. JP-A-2019-78825 discloses a liquid crystal panel including a capacitor connected immediately below a pixel electrode through a pixel contact hole.

In the electro-optic device disclosed in JP-A-2019-78825, a capacitive electrode making up the capacitor is composed of titanium nitride. Since the reflectance of titanium nitride is low, much of light impinging on the capacitive electrode is absorbed without being reflected, which leads to the temperature rise of the liquid crystal panel.

### SUMMARY

An electro-optic device according to an aspect of the subject application includes a transistor, a pixel electrode provided corresponding to the transistor, a first conductive layer including a first film provided between the transistor and the pixel electrode, and a second film provided between the first film and the pixel electrode and having a light reflectance higher than that of the first film, the first conductive layer being electrically connected to the pixel electrode through a contact hole extending to the first film through the second film, and a connecting member provided in the contact hole.

An electronic device according to an aspect of the subject application includes the above-described electro-optic device.

### BRIEF DESCRIPTION OF THE DRAWINGS

FIG. 1 is a plan view of an electro-optic device according to embodiment 1.

FIG. 2 is a sectional view of the electro-optic device taken along line II-II of FIG. 1.

FIG. 3 is an equivalent circuit diagram illustrating an electric configuration of an element substrate.

FIG. 4 is an explanatory diagram illustrating a cross-sectional structure of the display region of the element substrate.

FIG. 5 is an explanatory diagram illustrating a planar structure of the display region of the element substrate.

FIG. 6 is an explanatory diagram illustrating a planar structure of the display region of the element substrate.

FIG. 7 is an explanatory diagram illustrating a planar structure of the display region of the element substrate.

FIG. 8 is an explanatory diagram illustrating a planar structure of the display region of the element substrate.

FIG. 9 is an explanatory diagram illustrating a planar structure of the display region of the element substrate.

FIG. 10 is a sectional view taken along line X-X of FIG. 9.

FIG. 11 is a flowchart of a manufacturing process of a contact hole.

FIG. 12 is a sectional view illustrating an aspect of a manufacturing process.

FIG. 13 is a sectional view illustrating an aspect of a manufacturing process.

FIG. 14 is a sectional view illustrating an aspect of a manufacturing process.

FIG. 15 is a sectional view illustrating an aspect of a manufacturing process.

FIG. 16 is a sectional view illustrating an aspect of a manufacturing process.

FIG. 17 is a schematic view illustrating an example of an electronic device according to embodiment 2.

### DESCRIPTION OF EMBODIMENTS

Embodiments of the present disclosure are described below with reference to the accompanying drawings.

Note that in the following drawings, some components may not be drawn to scale for the purpose of the ease of illustration of the components.

In addition, in the following description, for convenience of explanation, an X axis, a Y axis, and a Z axis, which are orthogonal to each other, will be used as appropriate. Further, one direction along the X axis is referred to as an X1 direction, and a direction opposite to the X1 direction is referred to as an X2 direction. Similarly, one direction along the Y axis is referred to as a Y1 direction, and a direction opposite to the Y1 direction is referred to as a Y2 direction. One direction along the Z axis is referred to as a Z1 direction, and a direction opposite to the Z1 direction is referred to as a Z2 direction. Also, in the following description, a view in the Z1 direction or the Z2 direction will be referred to as a “plan view”, and a view in a direction perpendicular to a cross-section including the Z axis will be referred to as a “cross-sectional view”.

Further, in the following description regarding a substrate, the expression “on a substrate” means any one of a state of being disposed in contact with the substrate, a state of being disposed over the substrate via another structure, and a state of being partially disposed in contact with the substrate and partially disposed via another structure, for example. In addition, regarding a substrate, the expression “a top surface of a substrate” means a surface of the substrate on the Z1 direction side, and the expression “a bottom surface of a substrate” means a surface of the substrate on the Z2 direction side, for example.

### 1. Embodiment 1

In this embodiment, an example of a liquid crystal device will be described as an electro-optic device.

The liquid crystal device is an active drive type transmissive liquid crystal device including a thin film transistor (TFT) as a switching element for each pixel. This liquid crystal device is used, for example, as a light modulation device in a projection type display device, which will be described later. Note that in this embodiment, the projection type display device is an example of an electronic device.

### 1.1. Overview of Structure of Liquid Crystal Device

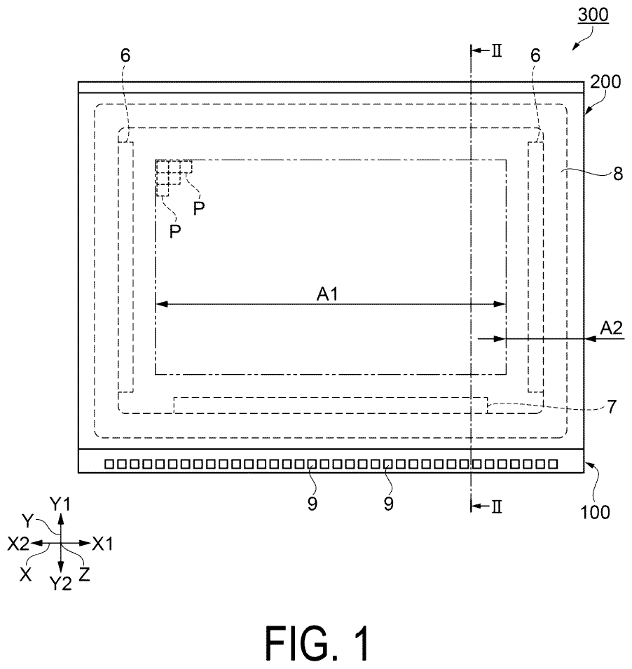

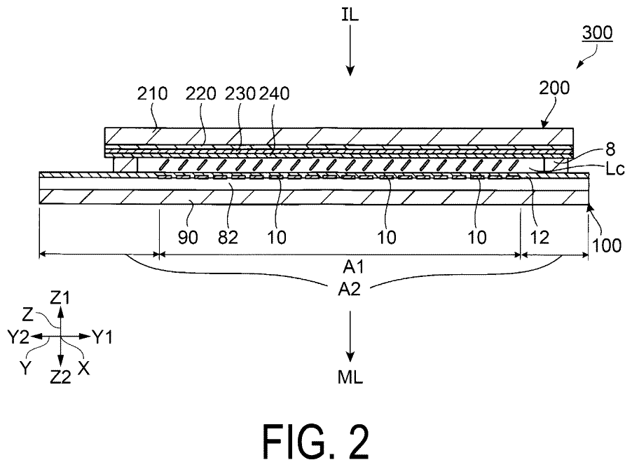

A structure of a liquid crystal device 300 according to this embodiment is described below with reference to FIGS. 1 and 2. FIG. 1 is a plan view of the liquid crystal device 300. FIG. 2 is a schematic cross-sectional configuration of the liquid crystal device 300 taken along line II-II of FIG. 1.

As illustrated in FIGS. 1 and 2, the liquid crystal device 300 includes an optically transparent element substrate 100, an optically transparent opposed substrate 200, a sealing member 8 provided in a frame shape, and a liquid crystal layer Lc. Note that “optically transparent” means the transmissivity to visible light, and means that the transmittance for visible light is preferably 50% or greater.

The liquid crystal device 300 includes a display region A1 for displaying images, and a peripheral region A2 located in a region around and outside the display region A1 in plan view.

A plurality of pixels P arranged in a matrix is provided in the display region A1. Note that while the shape of the liquid crystal device 300 and the display region A1 illustrated in FIG. 1 is quadrangle, the shape may be other shapes such as circular shape.

As illustrated in FIG. 2, the element substrate 100 and the opposed substrate 200 are disposed with the liquid crystal layer Lc therebetween.

In this embodiment, the opposed substrate 200 is disposed on the light incident side of the liquid crystal layer Lc, and the element substrate 100 is disposed on the light emission side of the liquid crystal layer Lc. Light IL having entered the opposed substrate 200 is modulated at the liquid crystal layer Lc, and emitted from the element substrate 100 as modulated light ML.

The element substrate 100 includes a plurality of interlayer insulating layers including a base 90 and an interlayer insulating layer 82, a pixel electrode 10, and an alignment film 12.

The base 90 is an optically transparent and insulating flat plate. The base 90 is, for example, a glass substrate or quartz substrate. A transistor, a relaying layer, or a conductive layer described later is disposed between the plurality of interlayer insulating layers.

The pixel electrode 10 is optically transparent. The pixel electrode 10 is formed of ITO (Indium Tin Oxide). Note that the pixel electrode 10 may be formed of transparent conductive materials such as IZO (Indium Zinc Oxide) and FTO (Fluorine-doped tin oxide). The thickness direction of the pixel electrode 10 coincides with the Z1 direction or Z2 direction.

The alignment film 12 is optically transparent and insulating. The alignment film 12 aligns the liquid crystal molecules of the liquid crystal layer Lc. Examples of the material of the alignment film 12 include silicon oxide (SiO₂) and polyimide.

The opposed substrate 200 includes a base 210, an insulating layer 220, a common electrode 230, and an alignment film 240.

The base 210 is an optically transparent and insulating flat plate. The base 210 is, for example, a glass substrate or quartz substrate.

The insulating layer 220 is optically transparent and insulating. Examples of the material of the insulating layer 220 include inorganic materials such as silicon oxide.

The common electrode 230 is an electrode disposed to face a plurality of the pixel electrodes 10, and may be referred to also as counter electrode. The common electrode 230 is formed of transparent conductive materials such as ITO, IZO and FTO, for example. The common electrode 230 and the pixel electrode 10 apply an electric field to the liquid crystal layer Lc.

The alignment film 240 is optically transparent and insulating.

The sealing member 8 is disposed between the element substrate 100 and the opposed substrate 200. The sealing member 8 is formed by using adhesive containing various curable resins such as epoxy resin or the like, for example. The sealing member 8 may include a gap material composed of inorganic materials such as glass.

The liquid crystal layer Lc is disposed inside the region surrounded by the element substrate 100, the opposed substrate 200 and the sealing member 8. The liquid crystal layer Lc is an electro-optic layer whose optical characteristics change in accordance with the electric field generated by the pixel electrode 10 and the common electrode 230. The liquid crystal layer Lc contains liquid crystal molecules with positive or negative dielectric anisotropy. The orientation of the liquid crystal molecules changes in accordance with the electric field applied to the liquid crystal layer Lc. The liquid crystal layer Lc modulates the incident light IL in accordance with the applied electric field.

As illustrated in FIG. 1, a plurality of scan line driving circuits 6, a data line driving circuit 7, and an external terminal 9 are disposed in the peripheral region A2 of the element substrate 100.

The external terminal 9 is a mounting terminal where an external connection line such as an FPC (Flexible Printed Circuit) not illustrated in the drawing is mounted. Various signals such as an image signal, synchronization signal, inspection signal, common potential, and power-source potential are supplied to the external terminal 9 from the outside through an external connection line.

### 1.2. Electric Configuration of Element Substrate

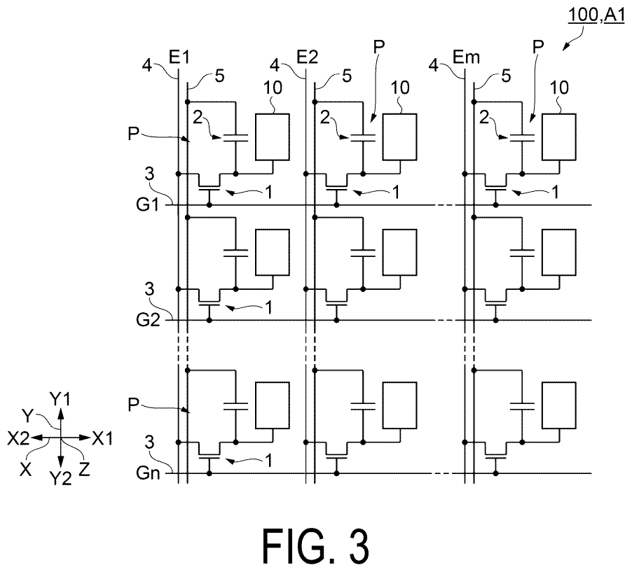

FIG. 3 is an equivalent circuit diagram illustrating an electric configuration of the element substrate 100.

As illustrated in FIG. 3, a plurality of transistors 1, n scan lines 3, m data lines 4, m capacitance lines 5, the pixel electrode 10, and a capacitive element 2 are provided in the display region A1 of the element substrate 100. The n and m are integers of 2 or greater.

The transistor 1 is provided corresponding to each intersection of the n scan lines 3 and the m data lines 4. The pixel electrode 10 is electrically connected to the drain region of the transistor 1.

Each of the n scan lines 3 is extended in the X1 direction, and the n scan lines 3 are arranged at even intervals the Y1 direction. Each of the n scan lines 3 is electrically connected to the gate electrode of the corresponding transistor 1. The n scan lines 3 is electrically connected to the scan line driving circuit 6 illustrated in FIG. 1.

The scan line driving circuit 6 line-sequentially supplies scanning signals G1, G2, . . . , and Gn to the 1 to n scan lines 3.

Each of the m data lines 4 is extended in the Y1 direction, and the m data lines 4 are arranged at even intervals in the X1 direction. The m data lines 4 are electrically connected to the source regions of the corresponding plurality of transistors 1. The m data lines 4 are electrically connected to the data line driving circuit 7 illustrated in FIG. 1.

The data line driving circuit 7 supplies image signals E1, E2, . . . , and Em to the 1 to m data lines 4.

The n scan lines 3 and the m data lines 4 are electrically isolated from each other, and disposed in a grid form in plan view. The region surrounded by the two scan lines 3 adjacent to each other and the two data lines 4 adjacent to each other corresponds to a pixel P.

Each of the m capacitance lines 5 is extended in the Y1 direction, and the m capacitance lines 5 are arranged at even intervals in the X1 direction. The capacitance line 5 is electrically isolated from the data line 4 and scan line 3, with spaces therebetween. A fixed potential such as ground potential or a common potential is supplied to the capacitance line 5 through the external terminal 9.

One electrode of the capacitive element 2 is electrically connected to the capacitance line 5.

The other electrode of the capacitive element 2 is electrically connected to the pixel electrode 10, and retains the potential of the image signal supplied to the pixel electrode 10. As described later, in this embodiment, one electrode of the capacitive element 2 is the capacitance line 5, and the other electrode of the capacitive element 2 is a relaying layer that electrically connects the pixel electrode 10 and the transistor 1.

### 1.3. Cross-Sectional Structure and Plane Structure of Display Region of Element Substrate

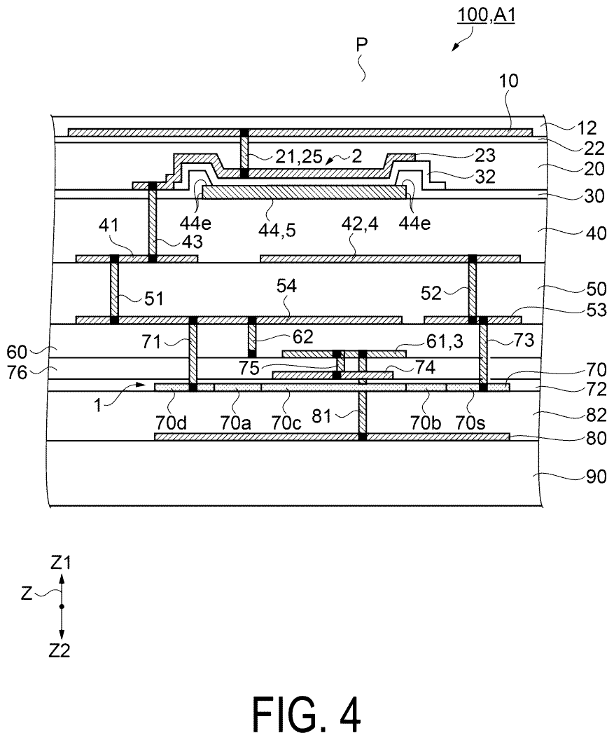

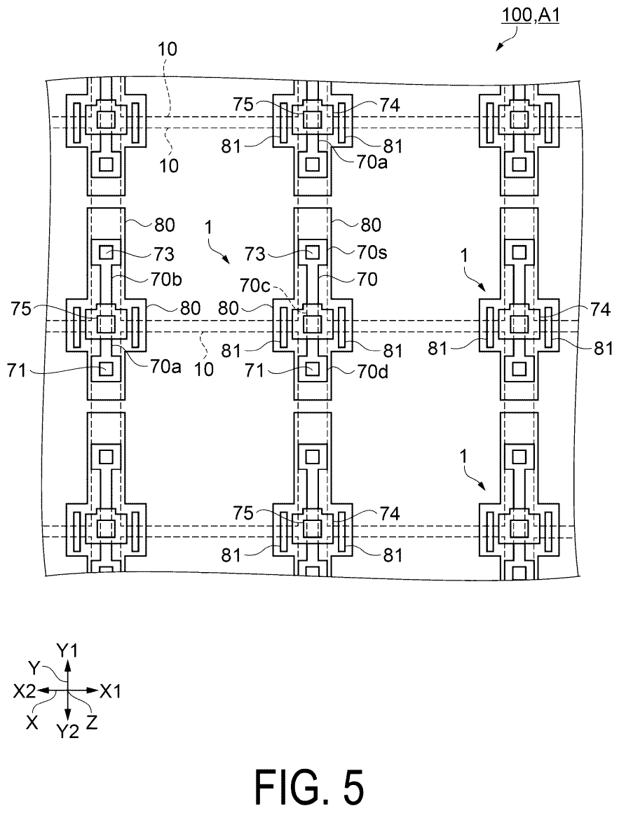

FIG. 4 is an explanatory diagram illustrating a cross-sectional structure of the display region A1 of the element substrate 100, and a sectional view illustrating a lamination relationship and an electrical connection relationship between layers. FIGS. 5 to 9 are plan views illustrating plane structures of main layers.

As illustrated in FIG. 4, in the display region A1, the element substrate 100 has a cross-sectional structure with insulating or conductive functional layers or functional films stacked on the base 90.

FIG. 5 is a plan view illustrating a plane structure from the base 90 to an interlayer insulating layer 76, and the solid line indicates a light-shielding layer 80, a semiconductor layer 70, a gate electrode 74, and contact holes 71, 73, 75 and 81. Note that in FIGS. 5 to 9, the position of the pixel electrode 10 is illustrated with the broken line to illustrate the positional relationship between the components in plan view. The pixel electrode 10 has a quadrangular shape.

As illustrated in FIG. 4, the light-shielding layer 80 is disposed between the base 90 and the interlayer insulating layer 82.

As illustrated in FIG. 5, the light-shielding layer 80 is provided to overlap the transistor 1 in plan view. The transistor 1 extends in the Y1 direction and Y2 direction between the four pixel electrodes 10. The light-shielding layer 80 includes a portion extending in the Y1 direction, a portion extending in the Y2 direction, and a protruding portion overlapping corner portions of the four pixel electrodes 10.

The light-shielding layer 80 is formed with a conductive material with a light-shielding property. As the conductive material with a light-shielding property, metals such as tungsten (W), titanium (Ti), chromium (Cr), iron (Fe), and aluminum (Al), and metal materials such as metal nitride and metal silicide may be used, for example. In the following description, the same applies to the conductive material with a light-shielding property, and it functions as a light-shielding layer. Note that the “light-shielding property” means a light-shielding property for visible light, and means that the transmittance of visible light is preferably smaller than 50%, more preferably 10% or smaller.

The interlayer insulating layer 82 is optically transparent and insulating. The interlayer insulating layer 82 is formed of an inorganic material such as silicon oxide (SiO₂), for example. In the following, the interlayer insulating layer is formed of the same material as the interlayer insulating layer 82.

As illustrated in FIG. 4, the transistor 1 is provided on the interlayer insulating layer 82.

The transistor 1 includes the semiconductor layer 70 with an LDD (Lightly Doped Drain) structure, the gate electrode 74, and a gate insulating layer 72.

The semiconductor layer 70 includes a drain region 70d, an LDD region 70a, a channel region 70c, an LDD region 70b and a source region 70s.

The channel region 70c is located at a center portion of the semiconductor layer 70. The LDD region 70b is located between the channel region 70c and the source region 70s. The LDD region 70a is located between the channel region 70c and the drain region 70d.

The semiconductor layer 70 is a polysilicon, and impurities for increasing the conductivity are doped in the region except for the channel region 70c, for example. The impurity concentration in the LDD region 70b and the LDD region 70a is lower than the impurity concentration in the source region 70s and the drain region 70d.

The gate electrode 74 is provided on the semiconductor layer 70 through the gate insulating layer 72.

The gate electrode 74 overlaps the channel region 70c of the semiconductor layer 70.

The gate electrode 74 is formed of polysilicon doped with impurities that increase the conductivity, for example. Note that the gate electrode 74 may be formed of conductive materials such as metal, metal silicide, and metal compound.

The gate insulating layer 72 is composed of a silicon oxide deposited by heat oxidation or CVD (Chemical Vapor Deposition).

The interlayer insulating layer 76 is provided on the transistor 1.

A conductive layer 61 is provided on the interlayer insulating layer 76. In this embodiment, the conductive layer 61 is a scan line 3. The conductive layer 61 is formed of a light-shielding conductive material.

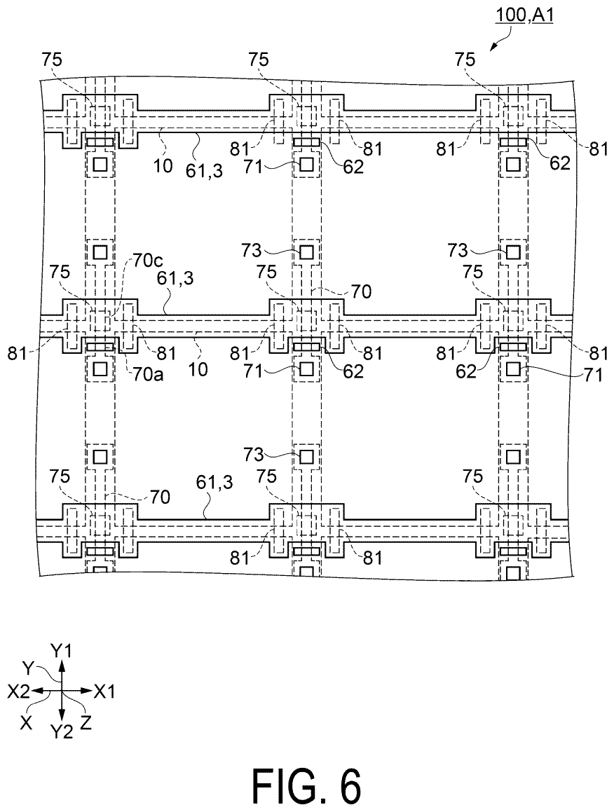

FIG. 6 is a plan view illustrating a plane structure of the conductive layer 61 provided on the interlayer insulating layer 76, with the conductive layer 61, a light blocking member 62, and the contact holes 71 and 73 indicated with the solid line, and the contact holes 75 and 81 and the semiconductor layer 70 indicated with the broken line.

As illustrated in FIG. 4, the conductive layer 61 is electrically connected to the gate electrode 74 through the contact hole 75 provided at the interlayer insulating layer 76. In addition, the conductive layer 61 is electrically connected to the light-shielding layer 80 through the contact hole 81 provided at the interlayer insulating layer 76 and the interlayer insulating layer 82. The light-shielding layer 80, to which a scanning signal is supplied from the conductive layer 61, serves as a back gate.

As illustrated in FIG. 6, the contact hole 81 is provided along the side surface on the X1 direction side and the side surface on the X2 direction side of the channel region 70c and the LDD region 70a, to block the channel region 70c and the LDD region 70b from the incident light from the side surface.

The conductive layer 61 extends in the X1 direction and X2 direction to overlap the region between the pixel electrodes 10 adjacent to each other in the Y1 direction and the Y2 direction. In addition, the conductive layer 61 includes a protruding portion that overlaps the corner portions of the four pixel electrodes 10.

The light blocking member 62 is provided to overlap the LDD region 70a in plan view. As illustrated in FIG. 4, the light blocking member 62 is electrically connected to a relaying layer 54, and the potential of the drain region 70d is applied to the light blocking member 62 through the contact hole 71 and the relaying layer 54.

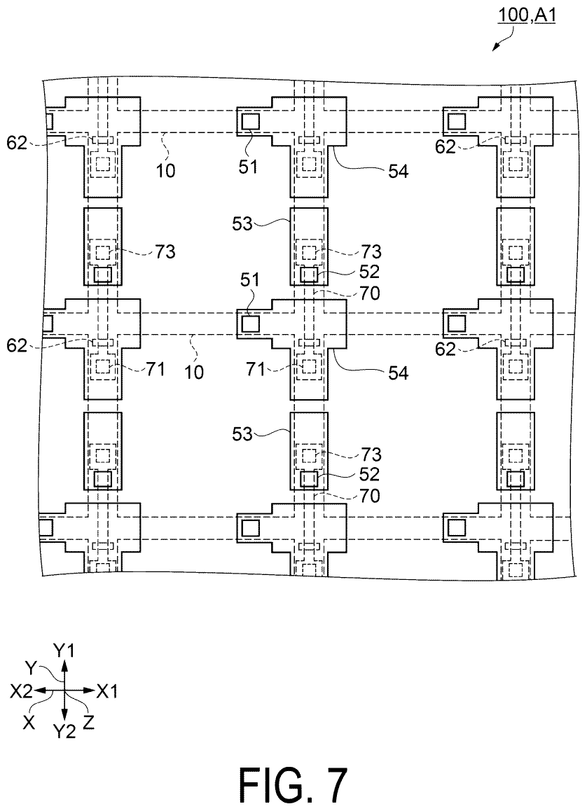

FIG. 7 is a plan view illustrating a plane structure of a relaying layer 53 and the relaying layer 54, with the relaying layers 53 and 54, the contact holes 51 and 52 indicated with the solid line, and the contact holes 71 and 73, the light blocking member 62, and the semiconductor layer 70 indicated with the broken line.

The relaying layer 53 and the relaying layer 54 are provided to overlap the region between the pixel electrodes 10 adjacent to each other in the X1 direction and the X2 direction.

The relaying layer 54 is provided at a position overlapping the corner portions of the four pixel electrodes 10, and includes a protruding portion that overlaps the corner portion of each pixel electrode 10.

As illustrated in FIG. 4, the relaying layer 54 is electrically connected to the drain region 70d of the semiconductor layer 70 through the contact hole 71 provided in an interlayer insulating layer 60 and the interlayer insulating layer 76.

The relaying layer 53 is electrically connected to the source region 70s of the semiconductor layer 70 through the contact hole 73 provided in the interlayer insulating layer 60 and the interlayer insulating layer 76.

An interlayer insulating layer 50 is provided on the relaying layer 53 and the relaying layer 54, and a relaying layer 41 and a conductive layer 42 are provided on the interlayer insulating layer 50.

In this embodiment, the conductive layer 42 is the data line 4. The relaying layer 41 and the conductive layer 42 are provided in the same layer, and are formed of a light-shielding conductive material.

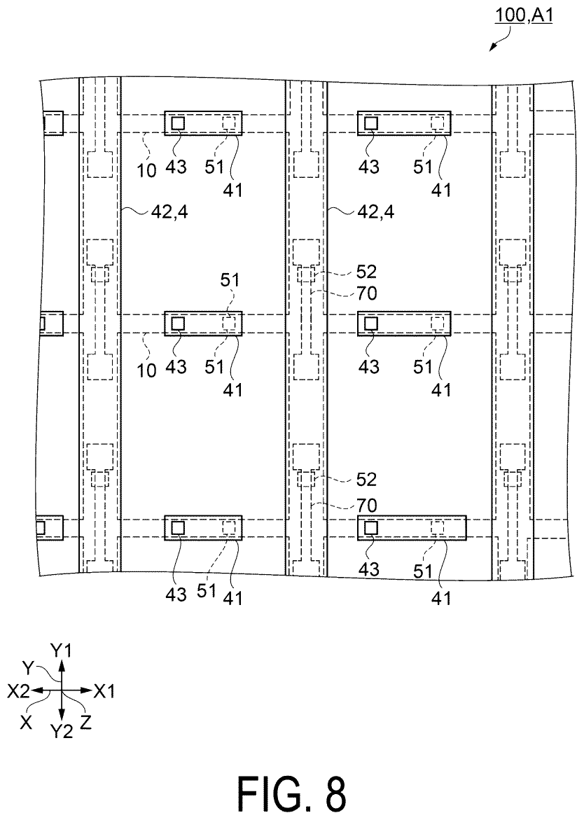

FIG. 8 is a plan view illustrating a plane structure of the relaying layer 41 and the conductive layer 42, with the relaying layer 41, the conductive layer 42, and a contact hole 43 indicated with the solid line, and the contact holes 51 and 52, and the semiconductor layer 70 indicated with the broken line.

The relaying layer 41 is provided to overlap the region between the pixel electrodes 10 adjacent to each other in the Y1 direction and the Y2 direction.

The conductive layer 42 extends in the Y1 direction and the Y2 direction to overlap the region between the pixel electrodes 10 adjacent to each other in the X1 direction and the X2 direction, so as to overlap the semiconductor layer 70.

As illustrated in FIG. 4, the relaying layer 41 is electrically connected to the relaying layer 54 through a contact hole 51. The conductive layer 42 is electrically connected to the relaying layer 53 through a contact hole 52.

An interlayer insulating layer 40 is provided on the relaying layer 41, the conductive layer 42, and the interlayer insulating layer 50. A conductive layer 44 and an interlayer insulating layer 30 are provided on the interlayer insulating layer 40. A capacitance insulating layer 32 and a relaying layer 23 are provided on the conductive layer 44 and the interlayer insulating layer 30.

In this embodiment, the conductive layer 44 is the capacitance line 5. The conductive layer 44 is formed of a light-shielding conductive material.

The relaying layer 23 is formed of a light-shielding conductive material, and is a light-shielding layer located closest to the pixel electrode 10. Note that in this embodiment, the relaying layer 23 functions as a light reflection layer.

The conductive layer 44, the relaying layer 23, and the capacitance insulating layer 32 form the capacitive element 2. More specifically, the portion where the conductive layer 44 and the relaying layer 23 face each other through only the capacitance insulating layer 32 is the capacitive element 2. In the capacitive element 2, the conductive layer 44 and the relaying layer 23 are capacitive electrodes.

The interlayer insulating layer 30 is provided to cover an end portion 44e of the conductive layer 44. In this embodiment, the end portion 44e includes the side surface of the conductive layer 44, and a part of the top surface of the conductive layer 44 along the corner between the side surface and the top surface of the conductive layer 44.

Thus, a step of the interlayer insulating layer 30 is formed in a region around the capacitive element 2. With the step of the interlayer insulating layer 30 formed in a region around the capacitive element 2, a configuration that less causes the short circuit of the relaying layer 23 and the conductive layer 44 can be achieved. In addition, since the step is provided along the end portion 44e of the conductive layer 44, the area of the capacitive element 2 can be maximized, and the capacitance of the capacitive element 2 can be improved.

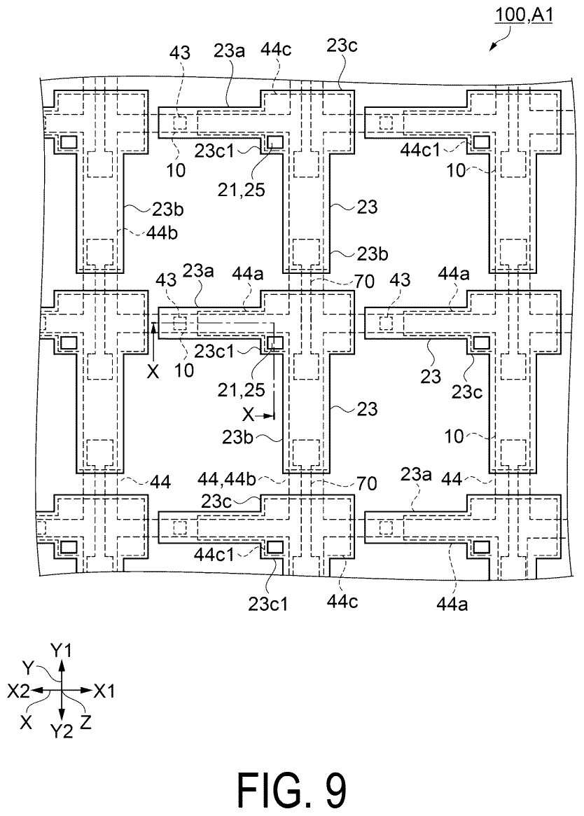

FIG. 9 is a plan view illustrating a plane structure of the relaying layer 23 and the conductive layer 44, with the relaying layer 23 and contact hole 21 indicated with the solid line, and the conductive layer 44, the contact hole 43, and the semiconductor layer 70 indicated with the broken line.

The relaying layer 23 is formed in an inverted L-shape in plan view, and includes an extension portion 23a extending in the X2 direction to overlap the region between the pixel electrodes 10 adjacent to each other in the Y1 direction and the Y2 direction, an extension portion 23b extending in the Y2 direction to overlap the region between the pixel electrodes 10 adjacent to each other in the X1 direction and the X2 direction, and a protruding portion 23c that overlaps the four corners of the pixel electrode. Note that a protruding portion 23c1 is a portion that overlaps the corner of the pixel electrode 10 at a corner portion between the extension portion 23a and the extension portion 23b in the protruding portion 23c. The corner portion between the extension portion 23a and the extension portion 23b may be referred to as a corner portion defined by the extension portion 23a and the extension portion 23b.

In this embodiment, the relaying layer 23 is an example of the first conductive layer, the extension portion 23a is an example of the first extension portion, the extension portion 23b is an example of the second extension portion, and the protruding portion 23c is an example of the protruding portion. In addition, the X2 direction is an example of the first direction, and the Y2 direction is an example of the second direction.

The conductive layer 44 includes an extension portion 44b extending in the Y1 direction and the Y2 direction between the pixel electrodes 10 adjacent to each other in the X1 direction and the X2 direction, an extension portion 44a that overlaps the extension portion 23a in plan view, and a protruding portion 44c that overlaps the protruding portion 23c in plan view. In addition, the protruding portion 44c includes a protruding portion 44c1 that overlaps the protruding portion 23c1 in plan view.

As illustrated in FIG. 4, the capacitance insulating layer 32 is provided between the conductive layer 44 and the relaying layer 23. In a region around the capacitive element 2, the capacitance insulating layer 32 is provided to cover the interlayer insulating layer 30. In this embodiment, the conductive layer 44 is an example of the second conductive layer, and the interlayer insulating layer 30 is an example of the insulating member.

The relaying layer 23 is electrically connected to the relaying layer 41 through the contact hole 43 provided in the interlayer insulating layer 30 and the interlayer insulating layer 40.

With the capacitance line 5 provided between the relaying layer 23 and the data line 4, the region between the relaying layer 23 and the data line 4 is shielded by the capacitance line 5, and the electrical coupling of the relaying layer 23 and the data line 4 is suppressed. Thus, superimposition of an image signal of another pixel P supplied to the data line 4 on an image signal as noise can be suppressed.

An interlayer insulating layer 20 and a protective layer 22 are provided on the relaying layer 23, the capacitance insulating layer 32, and the interlayer insulating layer 30. The protective layer 22 is composed of an optically transparent and moisture absorbing inorganic material such as BSG (Borosilicate Glass), for example. Note that the protective layer 22 may be omitted. The pixel electrode 10 is provided on the protective layer 22.

The pixel electrode 10 is electrically connected to the relaying layer 23 through a contact hole 21 provided in the interlayer insulating layer 20 and the protective layer 22. A contact plug 25 is provided inside the contact hole 21. The contact hole 21 and the contact plug 25 are pixel contacts.

As illustrated in FIG. 9, the contact hole 21 is provided at a position overlapping the protruding portion 23c1 in plan view. In addition, as illustrated in FIG. 4, the contact hole 21 is provided at a position overlapping the relaying layer 23, the capacitance insulating layer 32, and the conductive layer 44, but not overlapping the interlayer insulating layer 30.

### 1.4. Light Reflection Layer and Pixel Contact

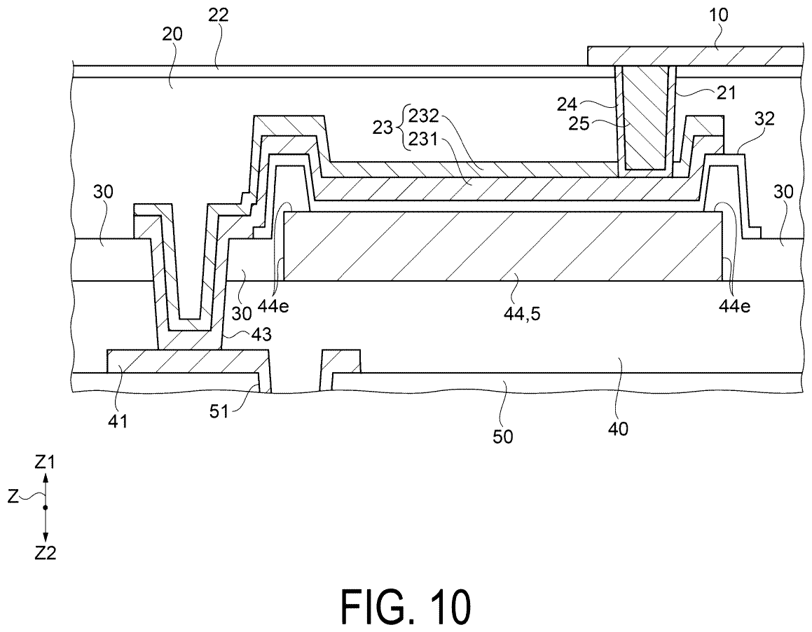

FIG. 10 is a sectional view taken along line X-X of FIG. 9, and illustrates a cross-sectional configuration on the interlayer insulating layer 50. The relaying layer 23 includes a conducting film 231 and a reflection film 232 provided on the conducting film 231. The conducting film 231 contains titanium nitride (TiN).

The reflection film 232 contains aluminum. Aluminum has a light reflectance higher than that of titanium nitride. Thus, the reflection film 232 functions as a light reflection layer. More specifically, the reflection film 232 reflects approximately 90% of light applied to the relaying layer 23. In other words, the reflection film 232 can reduce to approximately 10% the applied light that is absorbed by the relaying layer 23.

Thus, the liquid crystal device 300 of this embodiment can suppress the temperature rise of the liquid crystal device 300. In this embodiment, the conducting film 231 is an example of the first film, and the reflection film 232 is an example of the second film.

The pixel contact electrically connects the pixel electrode 10 and the relaying layer 23. In this embodiment, the pixel contact is composed of the contact hole 21 and the contact plug 25.

The contact hole 21 extends to the conducting film 231 through the reflection film 232. A contact plug 25 is provided inside the contact hole 21. In this embodiment, the contact plug 25 contains tungsten. Tungsten is a material that has an excellent heat resisting property and can be easily embedded into the contact hole with a high aspect ratio. Thus, tungsten can be neatly embedded in the contact hole 21 with a slender shape. In this manner, the reliability of the contact plug 25 serving as a connecting member can be improved.

A barrier member 24 is provided between the contact plug 25 and the contact hole 21. The barrier member 24 is formed of tungsten nitride (WN) or titanium nitride. Tungsten nitride or titanium nitride has an excellent adhesion to the interlayer insulating layer 20. Thus, the barrier member 24 can suppress peeling of the contact plug 25 in comparison with the case where no the barrier member 24 is provided. In this manner, the reliability of the contact plug 25 serving as a connecting member can be improved.

### 1.5. Manufacturing Method for Pixel Contact

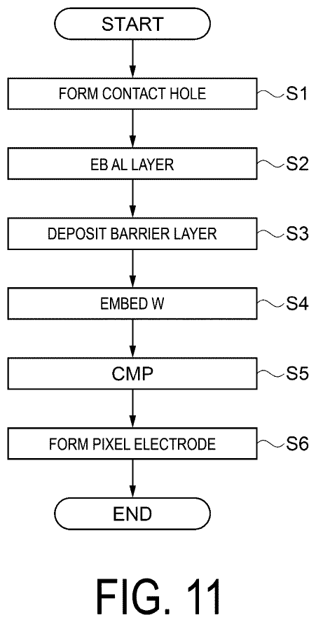

Next, with reference to FIGS. 11 to 16, a manufacturing method for a pixel contact is described.

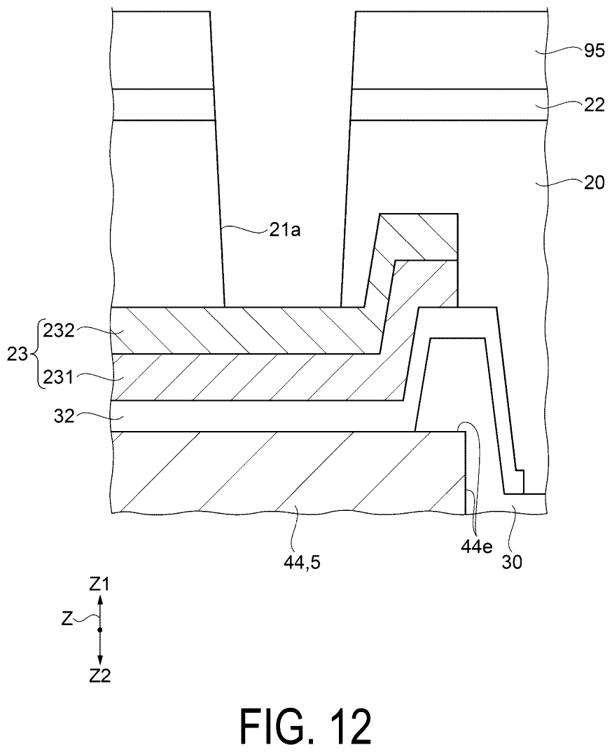

FIG. 11 is a flowchart illustrating a manufacturing method for a pixel contact. FIGS. 12 to 16 are sectional views illustrating an aspect of a manufacturing process of a pixel contact.

At step S1, a contact hole 21a is formed.

As illustrated in FIG. 12, in this step, the contact hole 21a that extends through the protective layer 22 and the interlayer insulating layer 20 and exposes the reflection film 232 at the bottom of the hole is formed with a photoresist 95. Deposits, in other words, residues and by-products of the etching, remaining in the contact hole 21a are then stripped. Ozone water (O₃) and dilute hydrofluoric acid solution are used for the stripping.

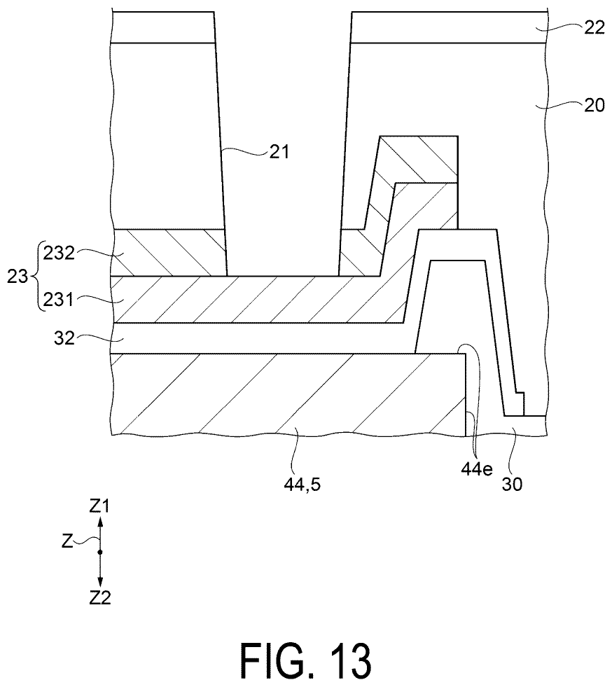

At step S2, the reflection film 232 composed of aluminum is etched back (EB). As illustrated in FIG. 13, in this step, the contact hole 21 that exposes the conducting film 231 is formed by etching the reflection film 232 with the protective layer 22 or the interlayer insulating layer 20 as masks. Chlorine etching gas is used to etch aluminum. The depot remaining in the contact hole 21a is then stripped. A stripping solution containing nitric acid is used for the stripping.

At step S3, a barrier layer 24a is deposited.

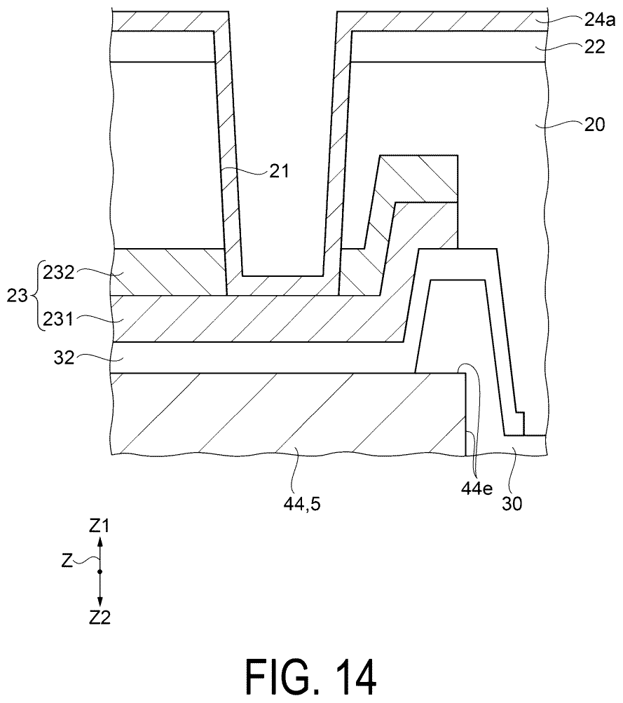

As illustrated in FIG. 14, the barrier layer 24a composed of tungsten nitride or titanium nitride is deposited by depositing tungsten nitride or titanium nitride on the inner wall of the contact hole 21 and the protective layer 22.

At step S4, tungsten is embedded in the contact hole 21.

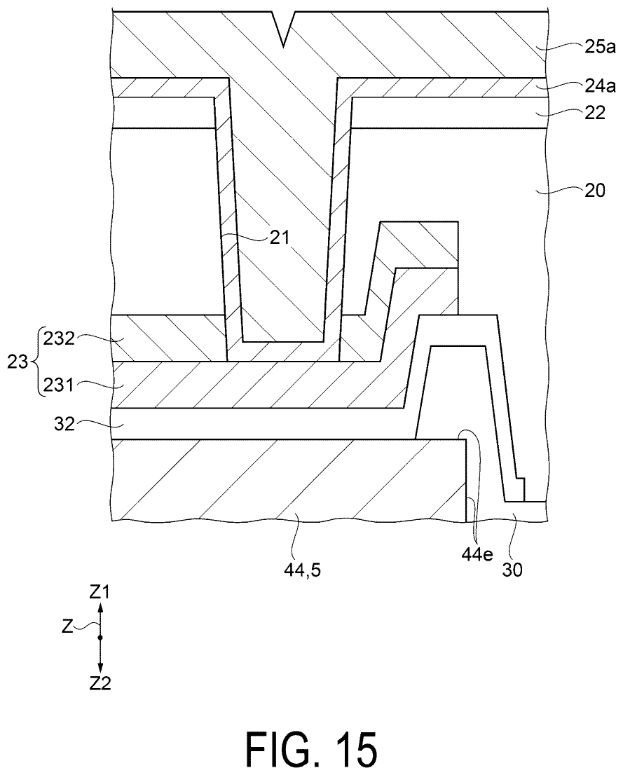

As illustrated in FIG. 15, in this step, a tungsten layer 25a is deposited on the barrier layer 24a by the CVD method. The tungsten layer 25a is neatly embedded in the contact hole 21.

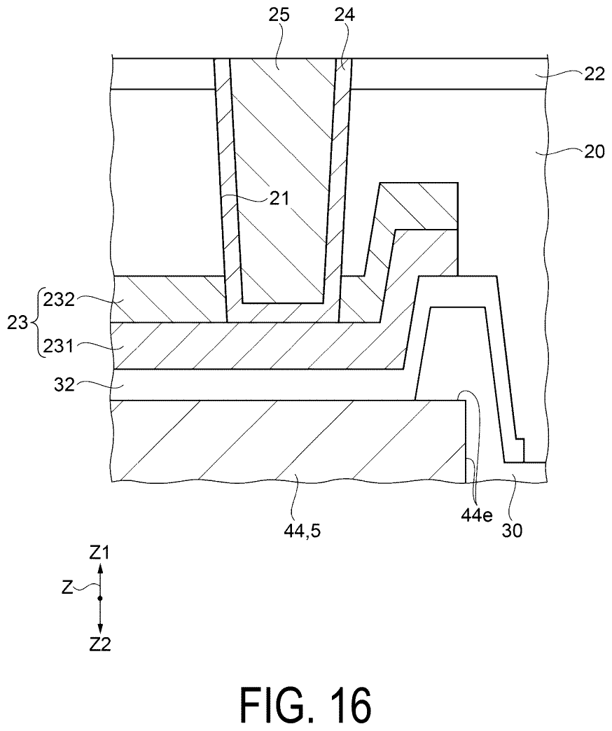

At step S5, CMP (Chemical Mechanical Polishing) is performed. As illustrated in FIG. 16, in this step, the tungsten layer 25a and the barrier layer 24a on the protective layer 22 are removed through CMP. In this step, the contact plug 25 composed of tungsten and the barrier member 24 between the contact plug 25 and the contact hole 21 are formed in the contact hole 21.

At step S6, the pixel electrode 10 is formed.

As illustrated in FIG. 10, in this step, ITO is deposited and patterned to form the pixel electrode 10. The alignment film 12 not illustrated in the drawing is formed on the pixel electrode 10.

As described above, with the liquid crystal device 300 serving as an electro-optic device of this embodiment, the following effects can be achieved.

The liquid crystal device 300 of this embodiment includes the transistor 1, the pixel electrode 10 provided corresponding to the transistor 1, the conducting film 231 serving as a first film provided between the transistor 1 and the pixel electrode 10, the reflection film 232 serving as a second film provided between the conducting film 231 and the pixel electrode 10 and having a light reflectance higher than that of the conducting film 231, the relaying layer 23 serving as a first conductive layer electrically connected to the pixel electrode 10 through the contact hole 21 extending to the conducting film 231 through the reflection film 232, and the contact plug 25 serving as a connecting member provided in the contact hole 21.

In this manner, the relaying layer 23 connected to the pixel electrode 10 through the contact plug 25 includes the reflection film 232. As a result, much of the light applied to the relaying layer 23 is reflected at the reflection film 232. Thus, the temperature rise of the liquid crystal device 300 can be suppressed.

In the liquid crystal device 300 of this embodiment, the conducting film 231 contains titanium nitride, and the reflection film 232 contains aluminum.

With the reflection film 232 composed of highly reflective aluminum, approximately 90% of the light applied to the relaying layer 23 can be reflected. In other words, the light absorbed by the relaying layer 23 can be suppressed to approximately 10%. Thus, the temperature rise of the liquid crystal device 300 can be suppressed.

In the liquid crystal device 300 of this embodiment, the contact plug 25 serving as a connecting member contains tungsten.

Tungsten is a material that has an excellent heat resisting property and can be easily embedded into the contact hole with a high aspect ratio. Thus, with the contact plug 25 that is a pixel contact and contains tungsten, the reliability of the conduction of the pixel electrode 10 and the relaying layer 23 can be improved.

The liquid crystal device 300 of this embodiment includes the barrier member 24 between the contact plug 25 serving as a connecting member and the side surface of the contact hole 21.

In this manner, with the barrier member 24, the function according to the material of the barrier member 24 and the like can be provided, and thus the reliability of the conduction of the pixel electrode 10 and the relaying layer 23 can be further improved.

In the liquid crystal device 300 of this embodiment, the barrier member 24 contains tungsten nitride or titanium nitride.

Tungsten nitride or titanium nitride is excellent in adhesion to the interlayer insulating layer 20. Thus, peeling of the contact plug 25 can be suppressed, and the reliability of the conduction of the pixel electrode 10 and the relaying layer 23 can be further improved.

In the liquid crystal device 300 of this embodiment, the relaying layer 23 serving as a first conductive layer includes the extension portion 23a serving as a first extension portion extending in the X2 direction as the first direction, the extension portion 23b serving as a second extension portion extending in the Y2 direction as the second direction intersecting the X2 direction, and the protruding portion 23c1 provided at a corner portion between the extension portion 23a and the extension portion 23b and overlapping the pixel electrode 10 in plan view, and the contact hole 21 overlaps the protruding portion 23c1 in plan view.

In this manner, the relaying layer 23 includes the extension portion 23a, the extension portion 23b, and the protruding portion 23c1. In other words, the relaying layer 23 has a large area. Thus, the relaying layer 23 can reflect a large amount of light. Thus, the temperature rise of the liquid crystal device 300 can be suppressed.

Furthermore, the contact hole 21 overlaps the protruding portion 23c1 in plan view. Thus, good conduction between the pixel electrode 10 and the relaying layer 23 can be achieved.

The liquid crystal device 300 of this embodiment includes the conductive layer 44 serving as a second conductive layer that faces the relaying layer 23 through the capacitance insulating layer 32 between the relaying layer 23 serving as a first conductive layer and the transistor 1, and the interlayer insulating layer 30 serving as an insulating member provided to cover the end portion 44e of the conductive layer 44 between the relaying layer 23 and the conductive layer 44, and the contact hole 21 overlaps the relaying layer 23 and the conductive layer 44 but does not overlap the interlayer insulating layer 30 in plan view.

As described above, the contact hole 21 overlaps the relaying layer 23 and the conductive layer 44 but does not overlap the interlayer insulating layer 30 in plan view. Here, the relaying layer 23 and the conductive layer 44 form the capacitive element 2, and the capacitive element 2 does not overlap the interlayer insulating layer 30. Thus, the contact hole 21 is provided at a position overlapping the capacitive element 2. In other words, the position overlapping the contact hole 21 is the capacitive element 2. Thus, the capacitance of the capacitive element 2 can be increased.

Furthermore, with the interlayer insulating layer 30 that covers the end portion 44e of the conductive layer 44, the short circuit between the relaying layer 23 and the conductive layer 44 can be suppressed, and the reliability of the capacitive element 2 can be increased.

### 2. Embodiment 2

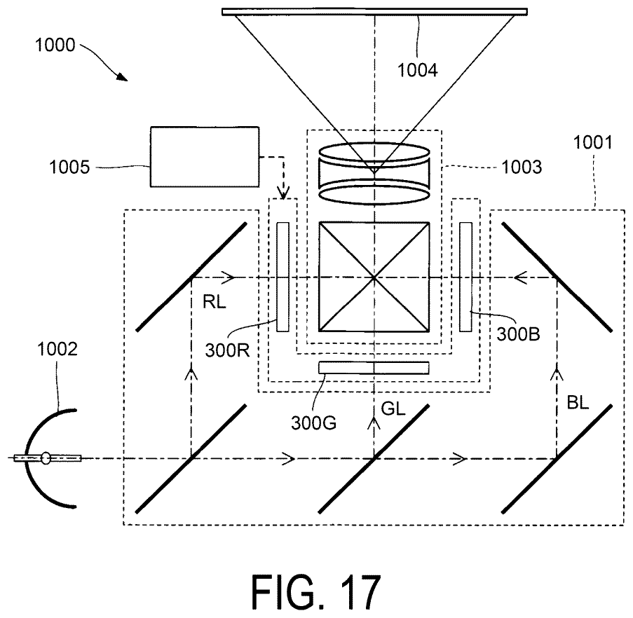

FIG. 17 is a schematic view illustrating an example of an electronic device, and illustrating a schematic configuration of a projection-type display device 1000 serving as an electronic device.

The projection-type display device 1000 is a three-plate projector including three liquid crystal devices 300 described above, for example. A liquid crystal device 300R corresponds to the red display color, a liquid crystal device 300G the green display color, and a liquid crystal device 300B the blue display color. A control unit 1005 includes a processor and a memory, and controls the operations of the liquid crystal devices 300R, 300G and 300B, for example.

Of the light emitted from an illumination device 1002 that is a light source, an illumination optical system 1001 supplies red light RL to the liquid crystal device 300R, green light GL to the liquid crystal device 300G, and blue light BL to the liquid crystal device 300B. The liquid crystal devices 300R, 300G and 300B serve as light modulation devices that modulate in accordance with the display image the color light RL, GL and BL supplied from the illumination optical system 1001.

A projection optical system 1003 combines the light emitted from the liquid crystal device 300R, the liquid crystal device 300G, and the liquid crystal device 300B, and projects the light to a screen 1004.

As described above, the projection-type display device 1000 serving as an electronic device of this embodiment includes the above-described liquid crystal device 300.

Thus, by employing the liquid crystal device 300 whose temperature rise is suppressed, the performance of the projection-type display device 1000 can be improved.

Note that the electronic device is not limited to the three-plate projector described as an example. For example, the projector may be a single-plate type, a two-plate type, or a projector equipped with four or more liquid crystal devices 300. In addition, the electronic device may be a smartphone, a personal digital assistant (PDA), a camera, a television, a car navigation device, a personal computer, a display, an electronic paper, a calculator, a videophone, a point of sale (POS), a printer, a scanner, a copier, a video player, or a device equipped with a touch panel, or the like.

Although the preferred embodiments have been described above, the present disclosure is not limited to the above-described embodiments. In addition, the configuration of each unit of the present disclosure can be replaced with any configuration that exhibits the same function as in the above-described embodiments, or any configuration can be added.

What is claimed is:

1. An electro-optic device comprising:
a transistor;
a pixel electrode provided corresponding to the transistor;
a first conductive layer including a first film provided between the transistor and the pixel electrode, and a second film provided between the first film and the pixel electrode and having a light reflectance higher than that of the first film, the first conductive layer being electrically connected to the pixel electrode through a contact hole extending to the first film through the second film; and
a connecting member provided in the contact hole.

2. The electro-optic device according to claim 1, wherein
the first film contains titanium nitride, and
the second film contains aluminum.

3. The electro-optic device according to claim 1, wherein the connecting member contains tungsten.

4. The electro-optic device according to claim 3, further comprising a barrier member between the connecting member and a side surface of the contact hole.

5. The electro-optic device according to claim 4, wherein the barrier member contains tungsten nitride or titanium nitride.

6. The electro-optic device according to claim 1, wherein
the first conductive layer includes a first extension portion extending along a first direction, a second extension portion extending along a second direction intersecting the first direction, and a protruding portion provided in a corner portion between the first extension portion and the second extension portion and overlapping the pixel electrode in plan view, and
the contact hole overlaps the protruding portion in plan view.

7. The electro-optic device according to claim 1, further comprising:
a second conductive layer provided to face the first conductive layer through a capacitance insulating layer between the first conductive layer and the transistor; and
an insulating member provided to cover an end portion of the second conductive layer between the first conductive layer and the second conductive layer, wherein
the contact hole overlaps the first conductive layer and the second conductive layer, but does not overlap the insulating member in plan view.

8. An electronic device comprising the electro-optic device according to claim 1.
